(19) United States
(12) Patent Application Publication
(10) Pub. No.: US 2005/0145946 A1
(43) Pub. Date: Jul. 7, 2005

(54) Over-voltage protection device in a portable equipment

(75) Inventors: Bo Bae Lee, Seoul (KR); Han Jung Choi, Seoul (KR)

Correspondence Address: Charles N.J. Ruggiero, Esq.;Ohlandt, Greeley, Ruggiero & Perle, L.L.P., 10th Floor, One Ladmark Square, Stamford, CT, 06901-2682, US

(73) Assignee: CURITEL COMMUNICATIONS, INC.

(21) Appl. No.: 10/979,315

(22) Filed: Nov. 2, 2004

(30) Foreign Application Priority Data
Dec. 5, 2003 (KR) 10-2003-0087841

(51) Int. Cl. H02H 3/20; H02H 3/24; H01L 21/00; H01L 21/84; H01L 23/62

(52) U.S. Cl. 257/355; 361/90

(57) ABSTRACT

Disclosed is an over-voltage protection device in a portable equipment. The device comprises an over-voltage detection signal generating unit for detecting over-voltage from power being applied from an external equipment and outputting an over-voltage detection signal; an over-voltage interruption unit controlled by the over-voltage detection signal of the over-voltage signal generating unit and determining whether the applied power should be supplied to a main circuit or not; and an over-voltage and backflow current interruption unit for transferring or interrupting power being applied to the main circuit and interrupting current flowing backward from the battery, depending on the determination of the over-voltage interruption unit.

### CROSS-REFERENCE TO RELATED APPLICATION

The entire disclosure of the Korean Patent Application No. 10-2003-0087841 filed on Dec. 5, 2003 including specification, claims, drawings and summary, is incorporated herein by reference in its entirety.

### BACKGROUND OF THE INVENTION

1. Field of the Invention

The present invention relates to a mobile communication terminal, and more particularly to an over-voltage protection device in a portable equipment having a battery mounted thereto, such as a mobile communication terminal, a PDA (Personal Digital Assistant), a notebook computer and a portable acoustic equipment.

2. Description of the Related Art

Recently, a variety of equipments such as a mobile communication terminal, a PDA, a notebook computer and a portable acoustic equipment etc. are manufactured to be portable owing to developments of a semiconductor and a battery manufacturing technologies, etc., so that a telephone call, an internet connection, an information management and an acoustic listening, etc. can be performed anywhere with a battery or a rechargeable battery mounted thereto.

By the way, when the portable equipment is charged in a home or a vehicle, or connected to other equipment such as a computer so as to communicate, it is essential to provide a circuitry for protecting an internal main circuit from over-voltage that instantaneously occurs due to, for example, a trouble of a corresponding power supply.

FIG. 1 is a circuit diagram showing a structure of an over-voltage protection circuit of a portable equipment according to the prior art. As shown in FIG. 1, the circuit comprises an external interface unit 10, an over-voltage detection unit 11 and a PMOS (P-channel Metal-Oxide Semiconductor) transistor 12, so that when the over-voltage detection unit 11 detects over-voltage from power applied via the external interface unit 10, the circuit regulates a gate of the PMOS transistor 12 so as to prevent the detected over-voltage from being transferred to the main circuit.

In other words, when the power is normally applied, the over-voltage detection unit 11 outputs a control signal in a ‘low state’ to the gate of the PMOS transistor 12 for activating the PMOS transistor 12 so as to transfer the power of the external interface unit 10 to the main circuit. When over-voltage occurs, the detection unit outputs a control signal in a ‘high state’ to the gate of the PMOS transistor 12 for deactivating the PMOS transistor 12 so as to interrupt the over-voltage.

The external interface unit 10 serves to be supplied with power for charging a battery or power necessary for communication into the portable equipment via an interface with an external equipment and thus to transfer the power to the internal main circuit.

However, in the above prior portable equipment, when the over-voltage detection unit 11 regulates the gate voltage of the PMOS transistor 12 for interrupting the over-voltage according as the over-voltage, which occurred from the external interface unit 10, is detected or not, since the PMOS transistor 12 is in an activated state on the point of occurrence of the over-voltage, the occurred over-voltage is transferred to the main circuit until the over-voltage detection unit 11 is operated after the over-voltage occurred, thereby damaging the main circuit. That is, when abrupt over-voltage is instantaneously applied, the main circuit could not be sufficiently protected until the over-voltage detection unit 11 is operated after the over-voltage occurred since it takes a time for the over-voltage detection unit 11 to operate.

Meanwhile, another embodiment of the prior over-voltage protection circuit in a portable equipment for solving the above-mentioned problems is shown in FIG. 2. As shown, a resistance R2 is connected between a gate and a source of a PMOS transistor 12 and thus over-voltage being applied via an external interface unit 10 is applied to both the gate and the source. Accordingly, the PMOS transistor 12 is deactivated by the voltage applied to the gate, so that it is in a deactivated state at the point that the over-voltage is applied.

Accordingly, the over-voltage applied from the external interface init 10 is prevented from being transferred to a main circuit until the over-voltage detection unit 10 is operated after the over-voltage occurred.

At this time, in order to maintain the PMOS transistor 12 to be in a deactivated state at the point that the over-voltage is applied, a control signal of the over-voltage detection unit 10 is provided to the gate of the PMOS transistor 12 by using transistors TR1, TR2. In this case, even when the power is not supplied from the external interface unit 10, power supplied from a battery connected to the portable equipment flows backward to the transistors TR1, TR2 via the activated PMOS transistor 12, so that current, which is charged in the battery 13, is unnecessarily consumed.

Accordingly, in the above prior art, when the gate and the source of the PMOS transistor 12 are connected by the resistance R2 and then the gate voltage of the PMOS transistor 12 is regulated to interrupt the over-voltage according as the over-voltage is detected or not, there is a problem that power of the battery 13 is unnecessarily consumed by the transistors TR1, TR2 which are connected to control the PMOS transistor 12. That is, though the main circuit is protected even when abrupt over-voltage is instantaneously applied, the power of the battery 13 is unnecessarily consumed by backflow current.

### SUMMARY OF THE INVENTION

Accordingly, the present invention has been made to solve the above-mentioned problems occurring in the prior art. The object of the present invention is to provide an over-voltage protection device in a portable equipment having a battery mounted thereto, such as a mobile communication terminal, a PDA, a notebook computer and a portable acoustic equipment, etc., wherein when over-voltage occurs due to a trouble of an external equipment in mounting the portable equipment to the external equipment, an over-voltage detection unit is maintained to be in an activated state at an initial state, so that the over-voltage is fundamentally prevented from being transferred to a main circuit until the over-voltage detection unit is operated after the over-voltage occurred, and when the battery is connected to the portable equipment, NMOS transistors of which gates are commonly connected are arranged in the opposite direction, so that current supplied from the battery is prevented from flowing backward.

In order to accomplish the objects, there is provided an over-voltage protection device in a portable equipment comprising an over-voltage detection signal-generating unit for detecting over-voltage from power being applied from an external equipment and outputting an over-voltage detection signal; an over-voltage interruption unit controlled by the over-voltage detection signal of the over-voltage signal-generating unit and determining whether the applied power should be supplied to a main circuit or not; and an over-voltage and backflow current interruption unit for transferring or interrupting power being applied to the main circuit and interrupting current flowing backward from the battery, depending on the determination of the over-voltage interruption unit.

Preferably, the over-voltage detection signal-generating unit comprises an over-voltage detecting part for detecting and monitoring the power being applied from the external equipment and outputting an over-voltage detection signal indicating whether the power is over-voltage or not; and a pull down resistance for pull-downing the over-voltage detection signal to a low state when initial state or over-voltage occurs.

Preferably, the over-voltage interruption unit comprises an over-voltage controlling part for outputting an over-voltage interruption signal determining whether the power applied from the external equipment should be supplied or not depending on the over-voltage detection signal of the over-voltage detection signal-generating unit; and a pull down resistance for pull-downing the over-voltage interruption signal to a low state when initial state or over-voltage occurs. The over-voltage controlling part may comprise a charge pump.

Preferably, the over-voltage and backflow current interruption unit is structured such that NMOS transistors of which gates are commonly connected are arranged in the opposite direction and a backward diode is parallel connected to a source and a drain of the respective NMOS transistor.

According to an embodiment of the invention, at initial state, the over-voltage detection signal-generating unit outputs an over-voltage detection signal in an activated state of a low state to the over-voltage interruption unit. Then, the over-voltage interruption unit is controlled by the over-voltage detection signal in the activated state, thereby outputting an over-voltage interruption signal in an activated state of a low state to the over-voltage and backflow current interruption unit.

In addition, when allowable voltage is applied via an external interface unit connected to the over-voltage detection signal-generating unit, the over-voltage detection signal-generating unit outputs an over-voltage detection signal in a deactivated state of a high state to the over-voltage interruption unit. Then, the over-voltage interruption unit is controlled by the over-voltage detection signal in the deactivated state, thereby outputting an over-voltage interruption signal in a deactivated state of a high state to the over-voltage and backflow current interruption unit.

Additionally, when over-voltage is applied via an external interface unit connected to the over-voltage detection signal-generating unit, the over-voltage detection signal-generating unit detects the over-voltage and thus outputs an over-voltage detection signal in an activated state of a low state to the over-voltage interruption unit. Then, the over-voltage interruption unit is controlled by the over-voltage detection signal in the activated state, thereby outputting an over-voltage interruption signal in an activated state of a low state to the over-voltage and backflow current interruption unit.

In addition, the over-voltage detection signal-generating unit and the over-voltage interruption unit are maintained to be in an activated state of a low state at initial state, such that when abrupt over-voltage is instantaneously applied via an external interface unit in mounting the external interface unit connected to the over-voltage detection signal-generating unit to the external equipment, the over-voltage and backflow current interruption unit interrupts the over-voltage from the main circuit at the point that the over-voltage is applied.

Additionally, when the portable equipment is provided with a battery, the over-voltage interruption unit applies an over-voltage interruption signal in an activated state of a low state to the over-voltage and backflow current interruption unit and the backward diode of the over-voltage and backflow current interruption unit interrupts the current flowing backward from the battery.

### BRIEF DESCRIPTION OF THE DRAWINGS

The above and other objects, features and advantages of the present invention will be more apparent from the following detailed description taken in conjunction with the accompanying drawings, in which:

FIG. 1 is a circuit diagram showing a structure of an over-voltage protection device in a portable equipment according to the prior art;

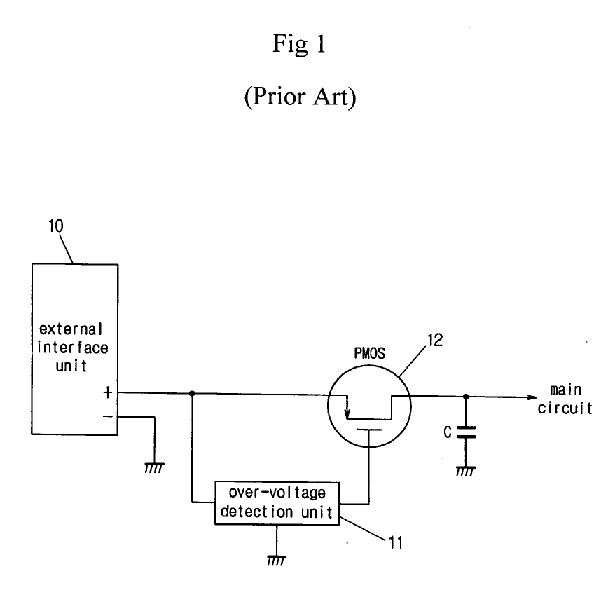

FIG. 2 is a circuit diagram showing a structure of an over-voltage protection circuit in a portable equipment according to another embodiment of the prior art; and

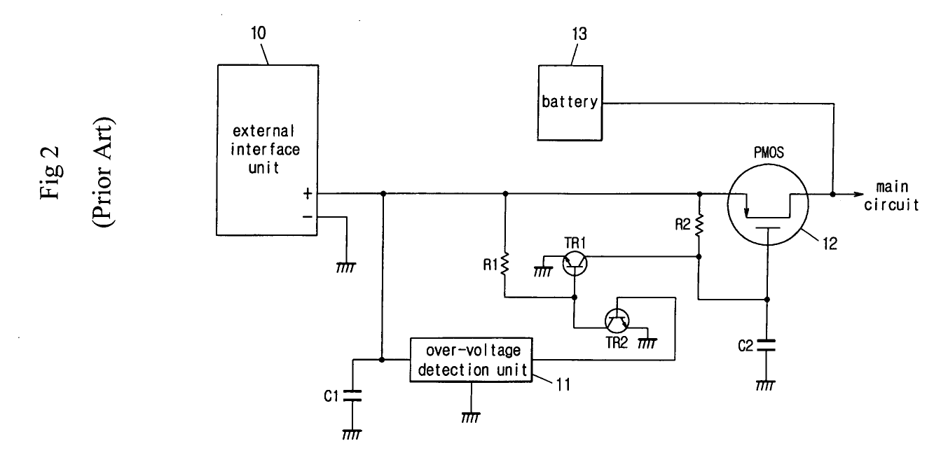

FIG. 3 is a circuit diagram illustrating a structure of an over-voltage protection device in a portable equipment according to the invention.

### DETAILED DESCRIPTION OF THE PREFERRED EMBODIMENTS

Hereinafter, preferred embodiments of the present invention will be described with reference to the accompanying drawings. In the following description of the present invention, a detailed description of known functions and configurations incorporated herein will be omitted when it may make the subject matter of the present invention rather unclear.

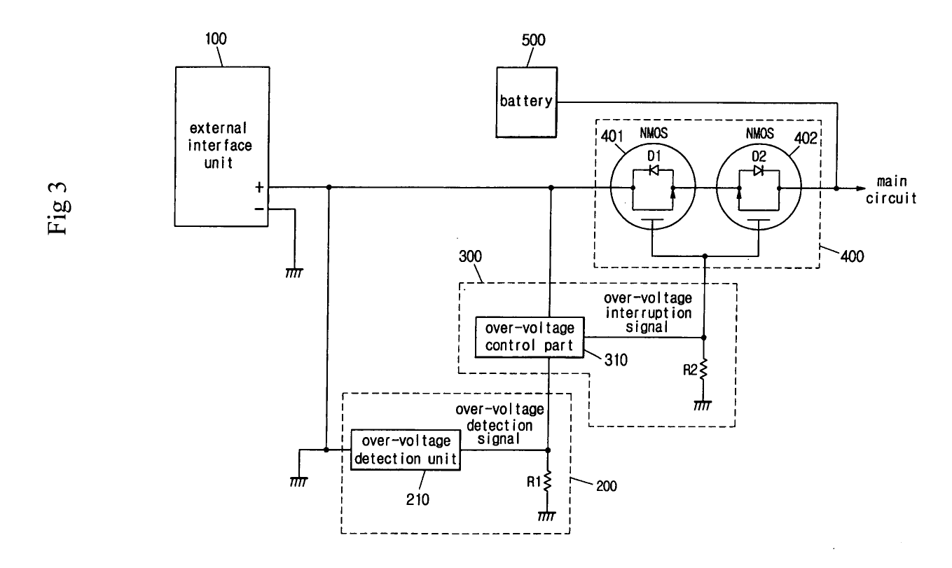

FIG. 3 is a circuit diagram illustrating a structure of an over-voltage protection device in a portable equipment according to the invention. As shown in FIG. 3, a typical external interface unit 100 is connected to an over-voltage detection signal-generating unit. The external interface unit 100 serves to be supplied with power for charging a battery 500 or power necessary for communication via an interface with an external equipment and thus to apply the power to an internal main circuit. An over-voltage detection signal-generating unit 200 detects over-voltage from the power applied by the external interface unit 100, and outputs an over-voltage detection signal. An over-voltage interruption unit 300 is connected to the over-voltage detection signal-generating unit 200, controlled by the over-voltage detection signal and determines whether the power applied to the main circuit via the external interface unit 100 should be supplied or not. An over-voltage and backflow current interruption unit 400 serves to transfer or interrupt the power applied to the main circuit and to interrupt current flowing backward from the battery 500, depending on the determination of the over-voltage interruption unit 300.

Referring to FIG. 3, the over-voltage detection signal-generating unit 200 comprises an over-voltage detecting part 210 for monitoring and detecting the power being inputted from the external interface unit 100 and outputting an over-voltage detection signal and a pull down resistance R1. The pull down resistance R1 pulls down the over-voltage detection signal to a low state when initial state or over-voltage occurs. In addition, the over-voltage interruption unit 300 comprises an over-voltage controlling part 310 and a pull down resistance R2. The over-voltage controlling part 310 outputs an over-voltage interruption signal, which determines whether the power applied from the external equipment should be supplied or not depending on the over-voltage detection signal. The pull down resistance R2 pulls down the over-voltage interruption signal to a low state when initial state or over-voltage occurs. The over-voltage controlling part 310 may consist of a charge pump.

The present invention can be applied to a portable equipment having a battery mounted thereto, such as a mobile communication terminal, a PDA, a notebook computer and a portable acoustic equipment, etc., and more particularly to a portable equipment which is supplied with power for charging a battery or power necessary for communication via an interface with an external equipment such as a Carkit and a USB (Universal Serial Bus), etc. and transfers the power to the internal main circuit.

According to the invention, the over-voltage and backward current interruption unit 400 is structured such that NMOS transistors 401, 402 of which gates are commonly connected are arranged in the opposite direction and diodes D1, D2 for interrupting backflow current are reversely connected between a source and a drain of the respective NMOS transistors 401, 402. The over-voltage and backflow current interruption unit 400 with such a structure receives the over-voltage interruption signal from the commonly connected gate and thus transfers or interrupts the power applied from the external interface unit 100 to or from the main circuit and interrupts current flowing backward from the battery 500.

According to the invention, the external interface unit 100 of the portable equipment is supplied with power for charging the battery 500 driving the portable equipment or power necessary for communication via an interface, such as a Carkit and a USB, thereby applying the power to the internal main circuit of the portable equipment.

At initial state, the over-voltage detection signal-generating unit 200 for detecting and monitoring the power applied from the external interface unit 100 to the main circuit, outputs an over-voltage detection signal in a ‘low state’, i.e. ‘activated state’ by the first pull down resistance R1, and the over-voltage interruption unit 300 also outputs an over-voltage interruption signal maintaining the ‘activated state’ of the ‘low state’ by the second pull down resistance R2.

Accordingly, the NMOS transistors 401, 402 of the over-voltage and backflow current interruption unit 400 is in the off position because voltage of the commonly connected gate becomes smaller than that of the source due to the over-voltage interruption signal in the activated state of the low state. Therefore, the power applied via the external interface unit 100 at initial state is not transferred to the main circuit.

After that, when allowable voltage is applied via the external interface unit 100, the over-voltage detection signal-generating unit 200 outputs over-voltage detection signal in a ‘high state’, i.e. ‘deactivated state’ by the over-voltage detecting part 210 for detecting and monitoring the allowable voltage applied from the external interface unit 100. Thus, the over-voltage controlling part 310 is operated and determines the power applied to the main circuit via the external interface unit 100 to be transferred, so that the over-voltage interruption unit 300 applies the over-voltage interruption signal in the ‘high state’, i.e., ‘deactivated state’ to the gate of the NMOS transistors 401, 402 and thus the voltage of the gates of the NMOS transistors 401, 402 becomes larger than that of the source. As a result, the NMOS transistors 401, 402 are in the on position and thus the power applied via the external interface unit 100 is transferred to the main circuit.

Meanwhile, when over-voltage occurs due to a trouble of the external equipment in mounting the external interface unit 100 to the external equipment or during using the mounted interface unit, the over-voltage is also transferred to the external interface unit 100. Then, the over-voltage detecting part 210 for detecting and monitoring the power applied from the external interface unit 100 detects over-voltage from the power applied via the external interface unit 100 and thus outputs the over-voltage detection signal in the ‘activated state’ of the ‘low state’ to the over-voltage controlling part 310.

After then, when the over-voltage interruption unit 300 is controlled by the over-voltage detection signal in the ‘activated state’ and thus determines the power applied to the main circuit via the external interface unit 100 to be interrupted, thereby outputting the over-voltage interruption signal in the ‘activated state’ of the ‘low state’, the NMOS transistors 401, 402 of the over-voltage and backflow current interruption unit 400 is operated and interrupts the over-voltage being applied to the main circuit.

Since the NMOS transistors 401, 402 of the over-voltage and backflow current interruption unit 400 are arranged in the opposite direction, when the over-voltage interruption signal in the ‘deactivated state’ of the ‘high state’ is applied to the commonly connected gate, the first NMOS transistor 401 is in the on position and the second NMOS transistor 402 which is oppositely arranged to the first transistor is in the off position. However, since the diode D2 for interrupting backflow current is reversely parallel connected to the source and the drain of the second NMOS transistor 402, the power having passed to the first NMOS transistor 401 is transferred to the gate of the main circuit via the diode D2 for interrupting backflow current. Accordingly, when the allowable voltage is applied via the external interface unit 100, the power applied via the external interface unit 100 is normally transferred to the main circuit.

Meanwhile, when the portable equipment is operated with the battery 500 mounted thereto, the power supplied from the battery 500 connected to the portable equipment flows backward and is transferred to the second NMOS transistor 402. At this time, the second NMOS transistor 402 that received the over-voltage interruption signal in the ‘activated state’ of the ‘low state’ from the over-voltage interruption unit 300 via the gate is deactivated to be in the off state, and the diode D2 for interrupting backflow current that is reversely connected to the source and the drain of the second NMOS transistor 402 interrupts the current flowing backward from the battery. Accordingly, the current charged in the battery 500 is prevented from flowing backward under a state that power is not supplied from the external interface unit 100.

In particular, when abrupt over-voltage is instantaneously applied to the external interface unit 100 in mounting the portable equipment to the external equipment, since the over-voltage detection signal-generating unit 200 and the over-voltage interruption unit 300 are maintained to be in the ‘activated state’ of the ‘low state’ at the initial state before mounting the portable equipment to the external equipment, the NMOS transistors 401, 402 of the over-voltage and backflow current interruption unit 400 is in the off position even at the point that the over-voltage occurs. Accordingly, the occurred over-voltage is fundamentally prevented from being transferred to the main circuit until the over-voltage detection signal-generating unit 200 is operated after the over-voltage occurred. As a result, according to the over-voltage protection device of the invention, the main circuit can be sufficiently protected even if abrupt over-voltage is instantaneously applied in mounting the external interface unit 100 to the external equipment.

As explained above, according to the invention, in a portable equipment having a battery mounted thereto, such as a mobile communication terminal, a PDA, a notebook computer and a portable acoustic equipment, when the over-voltage occurs due to a trouble of the external equipment in mounting the portable equipment to the external equipment, the over-voltage is fundamentally prevented from being transferred to the main circuit until the over-voltage detection unit is operated after the over-voltage occurred, by maintaining the over-voltage detection unit to be in ‘the activated state’ at initial state, so that the main circuit is protected from the abrupt over-voltage.

In addition, according to the invention, when a battery is connected to the portable equipment, NMOS transistors of which gates are commonly connected are arranged in the opposite direction, so that current supplied from the battery is prevented from flowing backward.

While the invention has been shown and described with reference to certain preferred embodiments thereof, it will be understood by those skilled in the art that various changes in form and details may be made therein without departing from the spirit and scope of the invention as defined by the appended claims.

1. An over-voltage protection device in a portable equipment comprising,
an over-voltage detection signal-generating unit for detecting over-voltage from power being applied from an external equipment and outputting an over-voltage detection signal;
an over-voltage interruption unit controlled by the over-voltage detection signal of the over-voltage signal-generating unit and determining whether the applied power should be supplied to a main circuit or not; and
an over-voltage and backflow current interruption unit for transferring or interrupting power being applied to the main circuit and interrupting current flowing backward from the battery, depending on the determination of the over-voltage interruption unit.

2. The device according to claim 1, wherein the over-voltage detection signal-generating unit comprises an over-voltage detecting part for detecting and monitoring the power being applied from the external equipment and outputting the over-voltage detection signal indicating whether the power is over-voltage or not; and a pull down resistance for pull-downing the over-voltage detection signal to a low state when initial state or over-voltage occurs.

3. The device according to claim 1, wherein the over-voltage interruption unit comprises an over-voltage controlling part for outputting an over-voltage interruption signal determining whether the power applied from the external equipment should be supplied or not depending on the over-voltage detection signal of the over-voltage detection signal-generating unit; and a pull down resistance for pull-downing the over-voltage detection signal to a low state when initial state or over-voltage occurs.

4. The device according to claim 1, wherein the over-voltage and backflow current interruption unit is structured such that NMOS transistors of which gates are commonly connected are arranged in the opposite direction and a backward diode is parallel connected to a source and a drain of the respective NMOS transistor.

5. The device according to claim 1, wherein at initial state, the over-voltage detection signal-generating unit outputs the over-voltage detection signal in an activated state of a low state to the over-voltage interruption unit, and the over-voltage interruption unit is controlled by the over-voltage detection signal in the activated state, thereby outputting an over-voltage interruption signal in an activated state of a low state to the over-voltage and backflow current interruption unit.

6. The device according to claim 1, wherein when allowable voltage is applied via an external interface unit connected to the over-voltage detection signal-generating unit, the over-voltage detection signal-generating unit outputs the over-voltage detection signal in a deactivated state of a high state to the over-voltage interruption unit and the over-voltage interruption unit is controlled by the over-voltage detection signal in the deactivated state, thereby outputting an over-voltage interruption signal in an deactivated state of a high state to the over-voltage and backflow current interruption unit.

7. The device according to claim 1, wherein when over-voltage is applied via the external interface unit connected to the over-voltage detection signal-generating unit, the over-voltage detection signal-generating unit detects the over-voltage and thus outputs the over-voltage detection signal in an activated state of a low state to the over-voltage interruption unit, and the over-voltage interruption unit is controlled by the over-voltage detection signal in the activated state, thereby outputting the over-voltage interruption signal in an activated state of a low state to the over-voltage and backflow current interruption unit.

8. The device according to claim 1, wherein the over-voltage detection signal-generating unit and the over-voltage interruption unit are maintained to be in an activated state of a low state at initial state, such that when abrupt over-voltage is instantaneously applied via an external interface unit in mounting the external interface unit connected to the over-voltage detection signal-generating unit to the external equipment, the over-voltage and backflow current interruption unit interrupts the over-voltage from the main circuit at the point that the over-voltage is applied.

9. The device according to claim 3, wherein the over-voltage controlling part comprises a charge pump.

10. The device according to claim 4, wherein when the portable equipment is provided with a battery, the over-voltage interruption unit applies the activated over-voltage interruption signal in an activated state of a low state to the over-voltage and backflow current interruption unit and the backward diode of the over-voltage and backflow current interruption unit interrupts the current flowing backward from the battery.

11. The device according to claim 1, wherein the portable equipment is a mobile communication terminal, a PDA, a notebook computer or a portable acoustic equipment to which a battery is mounted.
